(19) United States
(12) Patent Application Publication
(10) Pub. No.: US 2012/0268131 A1
(43) Pub. Date: Oct. 25, 2012

(54) MEASURING APPARATUS, CHARGING APPARATUS AND A MAGNETIC RESONANCE APPARATUS HAVING A MEASURING APPARATUS AND A CHARGING METHOD HEREFOR

(76) Inventors: Bernd Assmann, Furth (DE); Michael Frank, Erlangen (DE); Sven Heggen, Erlangen (DE); Ernst Mustafa, Furth (DE); Jürgen Rössler, Erlangen (DE)

(21) Appl. No.: 13/449,747

(22) Filed: Apr. 18, 2012

(30) Foreign Application Priority Data
Apr. 21, 2011 (DE) 102011007860.6

(51) Int. Cl. H02J 7/00; G01R 33/28

(52) U.S. Cl. 324/321; 320/107; 320/137

(57) ABSTRACT

A measuring apparatus for a magnetic resonance apparatus is proposed. The measuring apparatus has a charging apparatus and a mobile sensor unit for detecting a physiological signal of a patient. The mobile sensor unit includes a sensor element and an energy storage element which supplies electrical energy to the sensor element in an operating mode. The charging apparatus in a charging process increases a charging state of the energy storage element of the mobile sensor unit so that the mobile sensor unit can be coupled to the charging apparatus which has an energy buffering unit.

### CROSS REFERENCE TO RELATED APPLICATIONS

This application claims priority of German application No. 10 2011 007 860.6 filed Apr. 21, 2011, which is incorporated by reference herein in its entirety.

### FIELD OF INVENTION

The present invention relates to a measuring apparatus having a charging apparatus and at least one mobile sensor unit for detecting at least one physiological signal of a patient, and the at least one mobile sensor unit includes at least one sensor element and at least one energy storage element, which supplies electrical energy to the at least one sensor element during an operating mode, whereby the charging apparatus in a charging process increases a charging state of the at least one energy storage element of the at least one mobile sensor unit and to this end the at least one mobile sensor unit can be coupled to the charging apparatus.

### BACKGROUND OF INVENTION

In order to image the heart of a patient, it is necessary to synchronize an imaging apparatus, such as in particular a magnetic resonance apparatus, with a heart signal of the patient. To this end it is known for instance to use an EKG measuring apparatus with a mobile sensor unit to detect heart signals. The mobile sensor unit includes EKG electrodes and a rechargeable energy storage unit. The rechargeable energy storage unit of the mobile sensor unit can be recharged when the EKG measuring apparatus is in idle mode, in particular during night time hours, by means of a charging apparatus, whereby to this end the charging apparatus is connected to a control computer of the magnetic resonance apparatus. If the control computer is switched off when the magnetic resonance apparatus is in idle mode, a recharging of the energy storage unit of the mobile sensor unit is not possible.

### SUMMARY OF INVENTION

The object underlying the present invention is to provide a measuring apparatus, in which energy storage units are also charged when an external energy network is not available. The object is achieved by the features of the independent claims. Advantageous embodiments are described in the dependent claims.

The invention is based on a measuring apparatus having a charging apparatus and at least one mobile sensor unit for detecting at least one physiological signal of a patient and the at least one mobile sensor unit includes at least one sensor element and at least one energy storage element which supplies electrical energy to the at least one sensor element during an operating mode, whereby the charging apparatus in a charging process increases a charging state of the at least one energy storage element of the at least one mobile sensor unit and to this end the at least one mobile sensor unit can be coupled to the charging apparatus.

It is proposed that the charging apparatus comprises at least one energy buffering unit, as a result of which energy can be buffered for a charging process in order to charge the at least one energy storage element of the at least one sensor unit and thus the charging process can take place by means of the energy buffering unit of the charging apparatus even when an external energy source is not available. A mobile sensor unit is in this context understood to mean in particular a sensor unit, which is preferably separated from an external energy source in an operating mode of the measuring apparatus and/or from a wireless and/or cable-free sensor unit connected to further units of the measuring apparatus, such as for instance a further processing unit. An energy buffering unit is in this context understood to mean in particular a unit, to which energy, in particular electrical energy, is supplied and this energy is buffered for a further and/or subsequent use, in particular a charging process. Furthermore, ‘can be coupled’ is also to be understood in particular to mean that the at least one sensor unit comprises an in particular detachable connection with the charging apparatus for the purpose of an energy exchange and/or energy transmission from the charging apparatus to the at least one sensor unit. The physiological signal to be detected by means of the at least one mobile sensor unit can be formed by an EKG signal or a heart sound and/or a pulse signal and/or a respiration signal.

It is furthermore proposed for the charging apparatus to comprise an storage holder unit and the energy buffering unit to be arranged within the storage holder unit so as to be removable. The energy buffering unit can for instance be advantageously exchanged by an operator of the charging apparatus with a new energy buffering unit having a high storage capacity, for instance in the event of signs of ageing in the energy buffering unit, which in particular reduce the storage capacity of the energy buffering unit. The storage holder unit preferably comprises a cover, so that the energy buffering unit can also be mounted in a protected fashion within the storage holder unit.

A particularly simple exchange of the energy buffering unit for an operator can be advantageously achieved if the energy buffering unit comprises at least one energy buffering element, which is formed by an accumulator, such as for instance in the form of a conventional, rechargeable battery. Furthermore, the energy buffering unit can comprise at least one energy buffering element, which is formed by at least one capacitor, as a result of which a particularly cost-effective energy buffering unit can be achieved.

It is further proposed that the charging apparatus comprise an energy coupling unit for coupling to an external energy source, whereby the at least one energy storage element of the at least one sensor unit is charged by means of the energy buffering unit independently of a coupling of the charging apparatus to the external energy source. The at least one energy storage element can particularly advantageously be charged independently of the availability of an external energy source. In this context, external energy source is understood to mean in particular an energy source which is arranged outside of the measuring apparatus. For instance, a computing unit of a magnetic resonance apparatus can be embodied as an external energy source, whereby a charging process of the energy buffering element is dependent on operation of the computing unit.

In a further embodiment of the invention, it is proposed for the charging apparatus to comprise a first coupling unit for coupling a first sensor unit for a charging process and a second coupling unit for coupling a second sensor unit for a charging process. Advantageous charging of two sensor units can take place simultaneously.

Furthermore, the invention is based on a charging apparatus for a measuring apparatus. It is proposed that the charging apparatus comprises at least one energy buffering unit, as a result of which energy for a charging process can be buffered and the charging process can thus also take place when an external energy source is not available in order to charge the at least one energy storage means of the at least one mobile sensor unit by means of the energy storage unit of the charging apparatus.

The invention is also based on a magnetic resonance apparatus having a measuring apparatus, which comprises a charging apparatus and at least one mobile sensor unit for detecting at least one physiological signal of a patient, and the at least one mobile sensor unit comprises at least one sensor element and at least one energy storage element, which supplies electrical energy to the at least one sensor element during an operating mode, whereby the charging apparatus in a charging process increases a charging state of the at least one energy storage element of the at least one mobile sensor unit and the at least one mobile sensor can to this end be coupled to the charging apparatus.

It is proposed here for the charging apparatus to comprise at least one energy buffering unit, as a result of which energy for a charging process can be buffered and thus the charging process for charging the at least one energy storage means of the at least one mobile sensor unit can take place by means of the energy buffering unit of the charging apparatus even if an external energy source is not available.

It is also proposed that the magnetic resonance apparatus comprises a computing unit for evaluation of magnetic resonance images, whereby the computing unit comprises an energy coupling unit, by means of which the charging apparatus can be coupled to an energy network of the computing unit in order to charge the energy buffering unit. A simultaneous measuring operation and charging of the energy buffering unit can be achieved in a time-saving fashion and the energy buffering unit of the charging apparatus is charged for a subsequent charging of the at least one energy storage element of the at least one mobile sensor unit. The at least one energy storage unit of the at least one mobile sensor unit can thus be charged independently of an operating state of the computing unit and thus independently of the external energy source.

The invention is further based on a charging method for charging at least one energy storage element of a mobile sensor unit of a measuring apparatus. The charging method to this end includes a charging process, in which the at least one energy storage element is charged by means of a charging apparatus of the measuring apparatus, whereby, to this end, the at least one energy storage element is coupled to the charging apparatus.

It is proposed that electrical energy be stored in a first charging process in an energy buffering unit of the charging apparatus. The charging apparatus is preferably coupled to a computing unit of a magnetic resonance apparatus for the first charging process so that the energy buffering unit can be charged in an operating mode of the computing unit and/or the electrical energy can be transmitted to the energy buffering unit when the computing unit is in operating mode and stored there.

Furthermore, it is proposed that the energy stored in the energy buffering unit in a second charging process is transmitted to the at least one energy storage element of the mobile sensor unit. A charging process of the energy storage unit of the at least one mobile sensor unit can take place by means of the energy buffering unit independently of an external energy source. In this case the electrical energy is preferably transferred from the energy buffering unit of the charging apparatus to the at least one energy storage element of the at least one mobile sensor unit and stored in the at least one energy storage element.

It is also proposed, in a second charging process, for energy to be directly transmitted from an external energy source via the charging apparatus to the at least one energy storage element of the mobile sensor unit without changing a charging state of the energy buffering unit during this transmission. A direct transmission of energy for a charging process can thus be achieved in the presence of an external energy source.

### BRIEF DESCRIPTION OF THE DRAWINGS

Further advantages, features and details of the invention result from the exemplary embodiment described below and with the aid of the drawings, in which;

FIG. 1 shows a magnetic resonance apparatus having an inventive measuring apparatus in a schematic representation,

FIG. 2 shows the measuring apparatus in a schematic representation,

FIG. 3 shows a charging apparatus and two mobile sensor units of the measuring apparatus and

FIG. 4 shows an inventive charging method

### DETAILED DESCRIPTION OF INVENTION

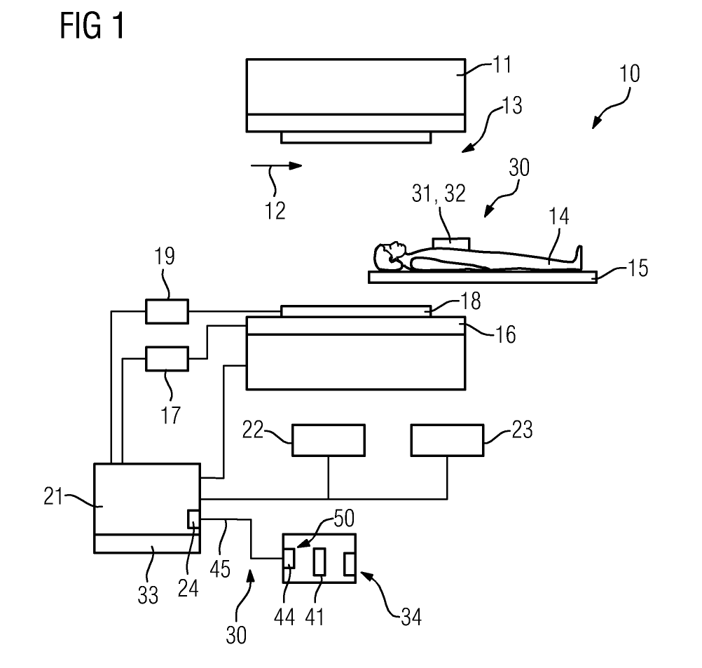

FIG. 1 shows an inventive magnetic resonance apparatus 10. The magnetic resonance apparatus 10 includes a main magnet 11 for generating a strong and in particular constant main magnetic field 12. Furthermore, the magnetic resonance apparatus 10 comprises a cylindrical receiving area 13 for receiving a patient 14, wherein the receiving area 13 is enclosed by the main magnet 11 in a circumferential direction. The patient 14 can be moved into the receiving area 13 by means of a patient couch 15 of the magnetic resonance apparatus 10.

The magnetic resonance apparatus 10 also comprises a gradient coil 16 for generating magnetic field gradients, which are used during imaging for local encoding. The gradient coil is controlled by means of a gradient control unit 17. Furthermore, the magnetic resonance apparatus 10 comprises a high frequency antenna 19 and a high frequency antenna unit 19 for exciting a polarization which is produced in the main magnetic field 12 generated by the main magnet 11. The high frequency antenna 18 is controlled by the high frequency antenna unit 19 and emits high frequency magnetic resonance sequences into an examination space, which is essentially formed by the receiving area 13. The magnetization is hereby deflected out of its position of equilibrium. In addition, magnetic resonance signals are received by means of the high frequency antenna unit 19.

The magnetic resonance apparatus 10 comprises a control unit formed of a computing unit 12 in order to control the main magnet 11, the gradient control unit 17 and the high frequency antenna unit 19. The computing unit 21 centrally controls the magnetic resonance apparatus 10, like for instance the implementation of a predetermined imaging gradient echo sequence. Control information like for instance imaging parameters, as well as reconstructed magnetic resonance images can be indicated on a display unit 22, for instance a monitor, of the magnetic resonance apparatus 10. In addition, the magnetic resonance apparatus 12 includes an input unit 23, by means of which information and/or parameters can be input by an operator during a measuring process.

The magnetic resonance apparatus 10 shown can naturally include further components, which usually comprise magnetic resonance apparatuses 10. A general functionality of a magnetic resonance apparatus 10 is also known to the person skilled in the art so that there is no need for a detailed description of the general components.

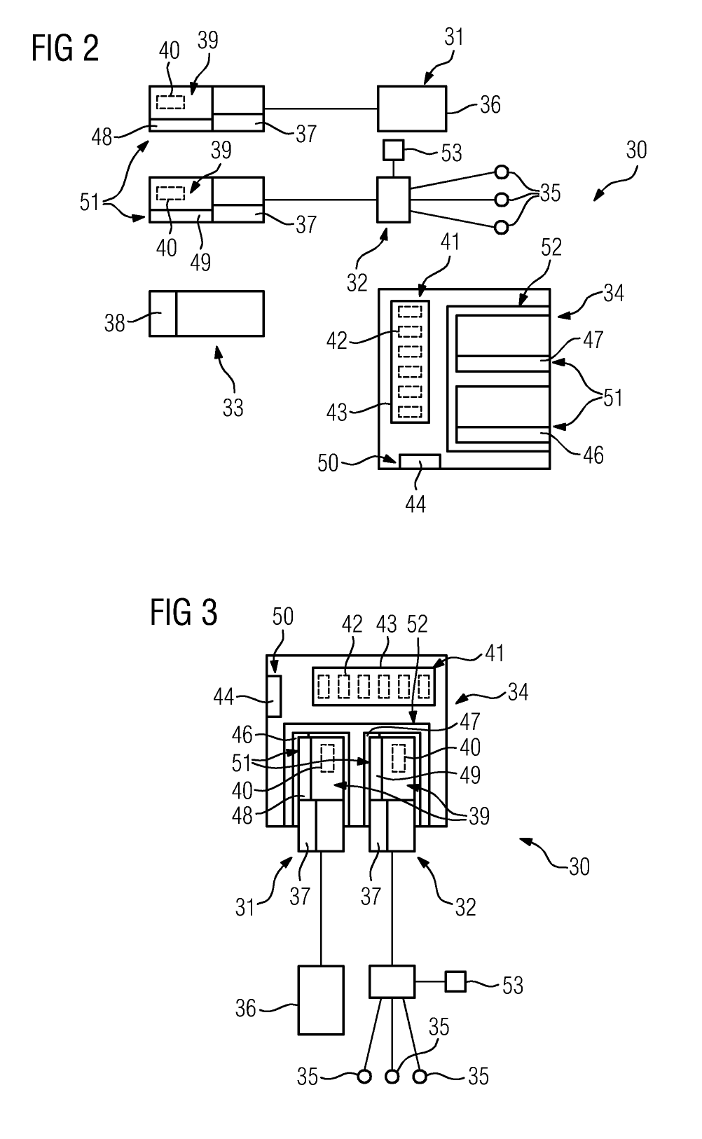

The magnetic resonance apparatus 10 also comprises the measuring apparatus 30, as is shown in more detail in FIGS. 2 and 3. The measuring apparatus 30 is designed to capture and/or detect heart signals and/or pulse signals of the patient 14 and to this end comprises two mobile sensor units 31, 32. The two mobile sensor units 31, 32 are embodied to be compatible in terms of magnetic resonance in order to prevent an unwanted interference in the measuring operation of the magnetic resonance apparatus 10. Furthermore, the measuring apparatus 30 includes a further processing unit 33 and a charging apparatus 34. In an alternative embodiment of the measuring apparatus 10, this may also comprise just one or more than two mobile sensor units 31, 32.

A first mobile sensor unit 31 comprises a sensor element 36, which is formed by a pulse receiver. A second mobile sensor unit 32 of the measuring apparatus 30 includes three sensor elements 35, which are each formed by EKG electrodes and a sensor element 53, which is formed by a breathing sensor. The two mobile sensor units 31, 32 are embodied separately from one another and separately from the further processing unit 33 and each comprise a signal transmission unit 37 for signal transmission between the mobile sensor units 31, 32 and the further processing unit 33. The signal transmission units 37 of the two mobile sensor units 31, 32 are embodied for wireless and/or cable-free signal transmission between the respective mobile sensor unit 31, 32 and the further processing unit 33. To this end, the electrical signals are sent to the further processing unit 33, which comprises a signal receiving unit 38. The transmitted signals can be formed here from digital or analog signals.

The further processing unit 33 includes a computing unit with software and/or computer programs stored on the computing unit for a further processing of the signals captured by the mobile sensor units 31, 32. Here the signals are prepared inter alia for generation of a trigger signal for the magnetic resonance apparatus 10, so that a synchronization of the magnetic resonance imaging with the trigger signal can take place for a magnetic resonance measurement. The further processing unit 33 of the measuring apparatus 30 is connected to the control unit of the magnetic resonance apparatus 10 via a data exchange unit (not shown in further detail). Alternatively, it is also possible for the further processing unit 33 of the measuring apparatus 30 to be integrated into the control unit of the magnetic resonance apparatus 10. The further processing unit 33 of the measuring apparatus 30 is also arranged outside of the receiving area 13 and also outside of an area permeated by the main magnetic field 12.

Furthermore, the two mobile sensor units 31, 32 each comprise an energy storage unit 39 with energy storage elements 40 in order to supply energy to the respective sensor elements 35, 36, 53. The two energy storage elements 39 of the two mobile sensor units 31, 32 are charged by way of the charging apparatus 34 of the measuring apparatus 30.

The charging apparatus 34 comprises an energy buffering unit 41, which includes several energy buffering elements 42. The charging apparatus 34 comprises an storage holder unit 43 for storing and/or arranging the energy buffering elements 42 of the energy buffering unit 41, within which the energy buffering elements 42 are arranged so as to be removable. For a cost-effective realization of the energy buffering unit 41, the energy buffering elements 42 can be formed of conventional rechargeable batteries, which, on account of the removable arrangement of the energy buffering elements 42, can be replaced with new rechargeable batteries by an operator of the charging apparatus 34 when the rechargeable batteries have aged. In addition, the energy buffering elements 42 can also be formed by capacitors and/or further energy buffering elements 42 which appear meaningful to the person skilled in the art. As an alternative to removable energy buffering elements 42, these can also be permanently arranged inside the charging apparatus 34. The storage holder unit 43 also comprises a cover, so that the energy buffering elements 42 can also be stored in a protected fashion within the storage holder unit 43.

The charging apparatus 34 includes a first energy transmission unit 50, by means of which electrical energy is transferred from an external energy source to the energy buffering unit 41. The first energy transmission unit 40 to this end includes an energy coupling unit 44, by means of which the charging apparatus 34 can be coupled to an external energy source. By means of the energy coupling unit 44, the charging apparatus 34 can be coupled to an energy coupling unit 24 of the computing unit 21 and the energy buffering unit 41 of the charging apparatus 34 can be charged by the electrical energy being transmitted from the computing unit 21 via the energy transmission unit 50 to the energy buffering unit 41 and stored therein. The energy coupling units 44, 42 of the charging apparatus 34 and/or of the computing unit 21 in the present exemplary embodiment each comprise a USB connection, whereby the two USB connections are connected to one another by means of a USB connection cable 45 of the first energy transmission unit 50 for the purpose of transmitting energy to the charging apparatus 34. An alternative embodiment of the energy coupling units 44, 24 of the energy transmission unit 50 is conceivable at any time.

The energy transmission from the computing unit 21 to the charging apparatus 34 is dependent here on an operating state of the computing unit 21, whereby energy can be transmitted to the charging apparatus 34 only during operation of the computing unit 21. If the computing unit 21 is by contrast in a switched-off state, no energy can be transferred.

The measuring apparatus 30 includes a second energy transmission unit 51 for transmitting energy from the energy buffering unit 41 of the charging apparatus 34 to the energy storage units 39 of both mobile sensor elements 31, 32. In this case the charging apparatus 34 includes a first coupling unit 46 of the second energy transmission unit 51 for a coupling of the first mobile sensor unit 31 to the charging apparatus 34 and a second coupling unit 47 of the second energy transmission unit 51 for a coupling of the second mobile sensor unit 32 to the charging apparatus 34. The first mobile sensor unit 31 comprises a coupling unit 48 of the second energy transmission unit 51 which corresponds to the first coupling unit 46 of the charging apparatus 34. Similarly, the second mobile sensor unit 32 also comprises a coupling unit 49 of the second energy transmission unit 51 which corresponds to the second coupling unit 47 of the charging apparatus 34. For a charging process of the energy storage elements 40 of the first mobile sensor unit 31 and/or the second mobile sensor unit 32, the two mobile sensor units 31, 32 are coupled to the charging apparatus 34 by means of the coupling units 46, 47, 48, 49, whereby the two coupling units 46, 47 are arranged in a receiving area 52 of the charging apparatus in order to receive the mobile sensor units (FIGS. 2 and 3).

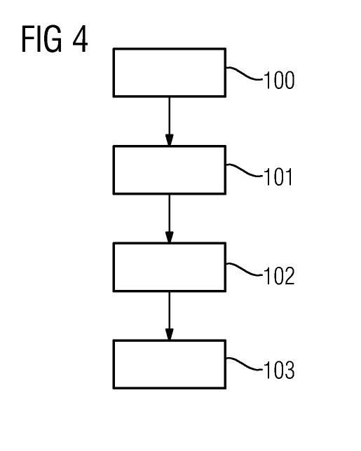

For the inventive charging method (FIG. 4) of the energy storage elements 40, at least one of the two mobile sensor units 31, 32 is initially coupled to the energy coupling unit 24 of the computing unit 21 by means of the energy coupling unit 44 in a coupling step 100 and a first charging process 101 is started during operation of the computing unit 21. In this first charging process 101, the energy buffering elements 42 of the energy buffering unit 41 are charged by electrical energy being fed from the computing unit 21 via the energy coupling units 24, 44 to the energy buffering elements 42 and being stored in the energy buffering elements 42.

The charging apparatus 34 can also be connected and/or coupled to the computing unit 21 by means of the energy coupling units 24, 44 in a period of time which lies outside of the period of time included in the first charging process 101.

In a second coupling step 102 of the charging method, at least one of the two mobile sensor units 31, 32 is initially coupled to the charging apparatus 34 by means of the coupling units 46, 47, 48, 49 of the charging apparatus 34. Subsequently, in a second charging process 103, electrical energy is transmitted from the energy buffering elements 42 via the coupling units 46, 47, 48, 49 to the energy storage elements 40 of the at least one mobile sensor unit 31, 32 and the transmitted electrical energy is stored in the energy storage elements 40 of the at least one mobile sensor unit 31, 32. The second charging process 103 is thus independent of an operating state of the computing unit 21 and/or a further external energy source (FIG. 4).

Thus for example, a normal measuring operation of the magnetic resonance apparatus 10 can take place during the day, wherein both the computing unit 21 is in operation and the mobile sensor units 321, 32 with charged energy storage units 39 are also available for capturing heart signals and/or pulse signals and/or breathing signals. At the same time as this measuring operation, the energy buffering unit 41 of the charging apparatus 41 is charged in the first charging process 101 on account of the coupling of the charging apparatus 34 to the computing unit 21. The computing unit 21 is in idle mode and/or switched off when the magnetic resonance apparatus 10 is idling, such as in particular at night. During these idle times, the second charging process 103 preferably takes place in order to charge the energy storage elements 40 of the mobile sensor units 31, 32, so that the two mobile sensor units 31, 32 are available for a next measuring operation of the magnetic resonance apparatus 10 with the charged energy storage elements 40.

Furthermore, provision can also be made for a direct charging of the energy storage elements 40 of the mobile sensor units 31, 32 to take place in the second charging process 103, by electrical energy being transmitted directly from the computing unit 21 via the charging apparatus 34 to the energy storage elements 40 of the mobile sensor units 31, 32. To this end, it is however necessary for the charging apparatus 34 to be connected and/or coupled to an external energy source during the second charging process 103. For instance, to this end the charging apparatus 34 can be connected to the computing unit 21 which is in operation during the second charging process 103. If, in the second charging process 103, a direct transmission of electrical energy takes place from the computing unit 21 via the charging apparatus 34 to the energy storage elements 40 of the mobile sensor units 31, 32, a charging state of the energy storage unit 41 remains unchanged.

1. A measuring apparatus, comprising:
a charging apparatus comprising an energy buffering unit; and
a mobile sensor unit for detecting a physiological signal of a patient,
wherein the mobile sensor comprises a sensor element and an energy storage element,
wherein the energy storage element is configured to supply electrical energy to the sensor element in an operating mode,
wherein the charging apparatus is configured to increase a charging state of the energy storage element in a charging process, and
wherein the mobile sensor unit is configured to be coupled to the charging apparatus.

2. The measuring apparatus as claimed in claim 1, wherein the charging apparatus comprises a storage holder unit and the energy buffering unit is arranged to be removable within the storage holder unit.

3. The measuring apparatus as claimed in claim 1, wherein the energy buffering unit comprises an energy buffering element formed by an accumulator.

4. The measuring apparatus as claimed in claim 1, wherein the energy buffering unit comprises an energy buffering element formed by a capacitor.

5. The measuring apparatus as claimed in claim 1, wherein the charging apparatus comprises an energy coupling unit for coupling to an external energy source.

6. The measuring apparatus as claimed in claim 5, wherein the energy storage element is charged by the energy buffering unit independently of the coupling to the external energy source.

7. The measuring apparatus as claimed in claim 1, wherein the charging apparatus comprises a first coupling unit for coupling a first sensor unit in the charging process and a second coupling unit for coupling a second sensor unit in the charging process.

8. A magnetic resonance apparatus, comprising:
a magnet;
a patient couch for receiving a patient in a cylindrical receiving area enclosed by the magnet; and
a measuring apparatus comprising:
a charging apparatus comprising an energy buffering unit;
a mobile sensor unit for detecting a physiological signal of the patient,
wherein the mobile sensor comprises a sensor element and an energy storage element,
wherein the energy storage element is configured to supply electrical energy to the sensor element in an operating mode,
wherein the charging apparatus is configured to increase a charging state of the energy storage element in a charging process, and
wherein the mobile sensor unit is configured to be coupled to the charging apparatus.

9. The magnetic resonance apparatus as claimed in claim 8, further comprising a computing unit for evaluating a magnetic resonance recording, wherein the computing unit comprises an energy coupling unit for coupling the charging apparatus to an energy network to charge the energy buffering unit.

10. A charging method for charging an energy storage element of a mobile sensor unit of a measuring apparatus, comprising:
charging the energy storage element by a charging apparatus of the measuring apparatus;
coupling the energy storage element to the charging apparatus; and
storing electrical energy in an energy buffering unit of the charging apparatus.

11. The charging method as claimed in claim 10, further comprising transmitting the electrical energy stored in the energy buffering unit to the energy storage element.

12. The charging method as claimed in claim 10, further comprising directly transmitting an electrical energy from an external energy source to the energy storage element via the charging apparatus.

13. The charging method as claimed in claim 12, wherein a charging state of the energy buffering unit is not changed during the transmission.
